(19) United States
(12) Patent Application Publication
(10) Pub. No.: US 2008/0041314 A1
(43) Pub. Date: Feb. 21, 2008

(54) Vaccum coater device and mechanism for transporting workpieces in same

(76) Inventor: Robert William Bruce, Loveland, OH (US)

Correspondence Address: JAMES P. DAVIDSON, ESQ., 8375 ASHMONT WAY, MASON, OH, 45040, US

(21) Appl. No.: 11/506,333

(22) Filed: Aug. 18, 2006

(51) Int. Cl. C23C 16/00

(52) U.S. Cl. 118/729

(57) ABSTRACT

An apparatus for providing a vacuum coating to workpieces positioned on a rake unit, including: a substantially rectangular central chamber; a first chamber located adjacent the central chamber on a first side, wherein the rake unit is positioned in the first chamber after workpieces are loaded thereon; a second chamber located adjacent the central chamber on a second side, wherein workpieces on the rake unit are heated to a predetermined temperature; a third chamber located adjacent the central chamber on a third side, wherein workpieces on the rake unit are coated in a desired manner; a fourth chamber located adjacent the central chamber on a fourth side, wherein workpieces on the rake unit are unloaded; and, a mechanism for transporting the rake unit from the first chamber to each of the second, third and fourth chambers in a desired sequence via the central chamber. The transporting mechanism further includes: a manipulator arm configured to grab the rake unit, the manipulator arm being movable so that the rake unit is pulled into and pushed out of the central chamber; and, a turntable associated with the manipulator arm, wherein an orientation of the rake unit with respect to the central chamber is controlled by rotation thereof

### BACKGROUND OF THE INVENTION

The present invention relates generally to a vacuum coater device and, in particular, to a mechanism for transporting workpieces in such vacuum coater device.

It will be appreciated that many parts in a gas turbine engine, including those in the high pressure turbine, combustor, and augmentor, are subjected to high temperatures. In order to enable such components to withstand such environment, it has been found desirable to apply a thermal barrier coating thereto (e.g., a durable physical vapor deposition (PVD) thermal barrier coating (TBC)). This is typically accomplished by means of a specialized device known as a vacuum coating apparatus, where the parts are subject to various process steps during the application cycle. Such process steps generally including loading the workpieces into the vacuum coating apparatus, heating the workpieces to a predetermined temperature, coating the workpieces in a desired manner, and unloading the workpieces from the vacuum coating apparatus.

The prior art discloses vacuum coaters which have performed the described process steps in essentially a linear fashion, where the workpieces are transported directly from one station to the next. This method of transporting workpieces is simple in its configuration, but requires a large amount of floor space. Because the number of different types of workpieces requiring such coating is increasing, a large number of tooling changes to accommodate them are also needed. Accordingly, the amount of useful coating time is interrupted, which translates into more down time for the apparatus.

One particular configuration is disclosed in U.S. Pat. Nos. 6,946,034 and 6,863,937 to Bruce et al., where a physical vapor deposition apparatus has a symmetrical arrangement with a preheat chamber and a loading chamber located on each side of a coating chamber. In this design, a rake unit loaded with parts to be coated may enter from either side of the coating chamber. This arrangement is inherently more efficient that an apparatus having a single linear load capability. Besides allowing a second rake unit to be heated in the preheat chamber while a first rake unit is undergoing the process in the coating chamber, additional rake units may be loaded with parts in the adjacent loading chamber. While this configuration is useful for its intended purpose, a still more efficient manner of transporting the rake units and their parts, when taking into account the overall coating cycle provided thereto, is preferred.

Accordingly, it would be desirable for a vacuum coating apparatus to be developed which is configured to provide flexibility for handling different types of workpieces. Besides increasing efficiency by minimizing down time, it would also be desirable for such vacuum coating apparatus to include a mechanism for transporting workpieces therein which permits several groups to undergo different steps of the coating process at the same time. Of course, it would be expected that such a vacuum coating apparatus also provide coatings in a quality manner and with low maintenance requirements. Further, it would be desirable for the vacuum coating apparatus to have a configuration which enables workpieces to be recovered from other stages of the coating process if a mishap occurs within one stage thereof

### BRIEF SUMMARY OF THE INVENTION

In accordance with a first exemplary embodiment of the invention, an apparatus for providing a vacuum coating to workpieces positioned on a rake unit is disclosed as including: a substantially rectangular central chamber; a first chamber located adjacent the central chamber on a first side, wherein the rake unit is positioned in the first chamber after workpieces are loaded thereon; a second chamber located adjacent the central chamber on a second side, wherein workpieces on the rake unit are heated to a predetermined temperature; a third chamber located adjacent the central chamber on a third side, wherein workpieces on the rake unit are coated in a desired manner; a fourth chamber located adjacent the central chamber on a fourth side, wherein workpieces on the rake unit are unloaded; and, a mechanism for transporting the rake unit from the first chamber to each of the second, third and fourth chambers in a desired sequence via the central chamber. The transporting mechanism further includes: a manipulator arm configured to grab the rake unit, the manipulator arm being movable so that the rake unit is pulled into and pushed out of the central chamber; and, a turntable associated with the manipulator arm, wherein an orientation of the rake unit with respect to the central chamber is controlled by rotation thereof

In a second exemplary embodiment of the invention, a process for transporting a rake unit having a plurality of workpieces thereon through a vacuum coater during a coating cycle is disclosed as including the following steps: providing a first rake unit to a loading chamber; pulling the first rake unit from the loading chamber into a central chamber; rotating the first rake unit into alignment with a heating chamber; pushing the first rake unit from the central chamber into the heating chamber for a predetermined time period; pulling the first rake unit from the heating chamber into the central chamber; rotating the first rake unit into alignment with a coating chamber; pushing the first rake unit from the central chamber into a coating chamber until docked therein; pulling the first rake unit from the coating chamber into the central chamber after a coating procedure has been applied to the workpieces; rotating the first rake unit into alignment with an unloading chamber; pushing the first rake unit from the central chamber into the unloading chamber; and, removing the first rake unit from the unloading chamber after a predetermined cooling period. Additional rake units may be transported through the chambers of the vacuum coater concurrently with the first rake unit.

### BRIEF DESCRIPTION OF THE DRAWINGS

FIG. 1 is a top plan view of a vacuum coating apparatus, where a rake unit is shown as being positioned within a loading chamber;

FIG. 2 is a front elevation view of the vacuum coating apparatus taken along line 2-2 in FIG. 1, where the rake unit is shown as being positioned within the loading chamber;

FIG. 3 is a top plan view of the vacuum coating apparatus depicted in FIGS. 1 and 2, where the rake unit is shown as being positioned within a central chamber and aligned with the loading chamber;

FIG. 4 is a front elevation view of the vacuum coating apparatus taken along line 4-4 of FIG. 3, where movement of a manipulator arm is depicted as transporting the rake unit from the loading chamber to the central chamber;

FIG. 5 is an enlarged, top plan view of the rake unit and a portion of the manipulator arm depicted in FIGS. 1 and 2;

FIG. 6 is a top plan view of the vacuum coating apparatus depicted in FIG. 3, where the rake unit is shown as being positioned within the central chamber and rotated into alignment with a heating chamber;

FIG. 7 is a top plan view of the vacuum coating apparatus depicted in FIG. 6, where the rake unit is shown as being positioned within the heating chamber;

FIG. 8 is a side elevation view of the vacuum coating apparatus taken along line 8-8 in FIG. 7, where movement of the manipulator arm is depicted as transporting the rake unit from the central chamber to the heating chamber;

FIG. 9 is a top plan view of the vacuum coating apparatus depicted in FIG. 7, where the rake unit is shown as being positioned within the central chamber and rotated into alignment with a coating chamber;

FIG. 10 is a top plan view of the vacuum coating apparatus depicted in FIG. 9, where the rake unit is shown as being positioned within the coating chamber;

FIG. 11 is a front elevation view of the vacuum coating apparatus taken along line 11-11 in FIG. 10, where movement of a manipulator arm is depicted as transporting the rake unit from the central chamber to the coating chamber;

FIG. 12 is a top plan view of the vacuum coating apparatus depicted in FIG. 10, where the rake unit is shown as being positioned within the central chamber and rotated into alignment with an unloading chamber;

FIG. 13 is a top plan view of the vacuum coating apparatus depicted in FIG. 12, where the rake unit is shown as being positioned within the unloading chamber;

FIG. 14 is a side elevation view of the vacuum coating apparatus taken along line 14-14 in FIG. 13, where movement of the manipulator arm is depicted as transporting the rake unit from the central chamber to the unloading chamber;

FIG. 15 is a partial top plan view of the vacuum coating apparatus depicted in FIG. 13, where rake units are shown as being positioned within the loading chamber and removed from the unloading chamber after a cooling period;

FIG. 16 is a front elevation view of the vacuum coating apparatus taken along line 2-2 of FIG. 1, where a manipulator arm having an alternative configuration is depicted as being in the retracted position within the central chamber;

FIG. 17 is a front elevation view of the vacuum coating apparatus taken along line 11-11 of FIG. 10, where the manipulator arm having an alternative configuration is depicted as being in the extended position while engaging a rake unit within the coating chamber;

5 FIG. 18 is a top plan view similar to FIG. 10, where a first rake unit is shown as being positioned within the heating chamber and a second rake unit is shown as being positioned within the loading chamber;

FIG. 19 is a top plan view similar to FIG. 18, where the first rake unit is shown as being positioned within the coating chamber, the second rake unit is shown as being positioned within the heating chamber, and a third rake unit is shown as being positioned within the loading chamber;

FIG. 20 is a top plan view similar to FIG. 13, where the first rake unit is shown as being positioned within the unloading chamber, the second rake unit is shown as being positioned within the coating chamber, and the third rake unit is shown as being positioned within the heating chamber;

FIG. 21 is a top plan view similar to FIG. 20, where the first rake unit is shown as having been removed from the unloading chamber, the second rake unit is positioned within the unloading chamber, and the third rake unit is positioned within the coating chamber; and,

FIG. 22 is a top plan view similar to FIG. 21, where the second rake unit is shown as having been removed from the unloading chamber and the third rake unit is positioned within the unloading chamber.

### DETAILED DESCRIPTION OF THE INVENTION

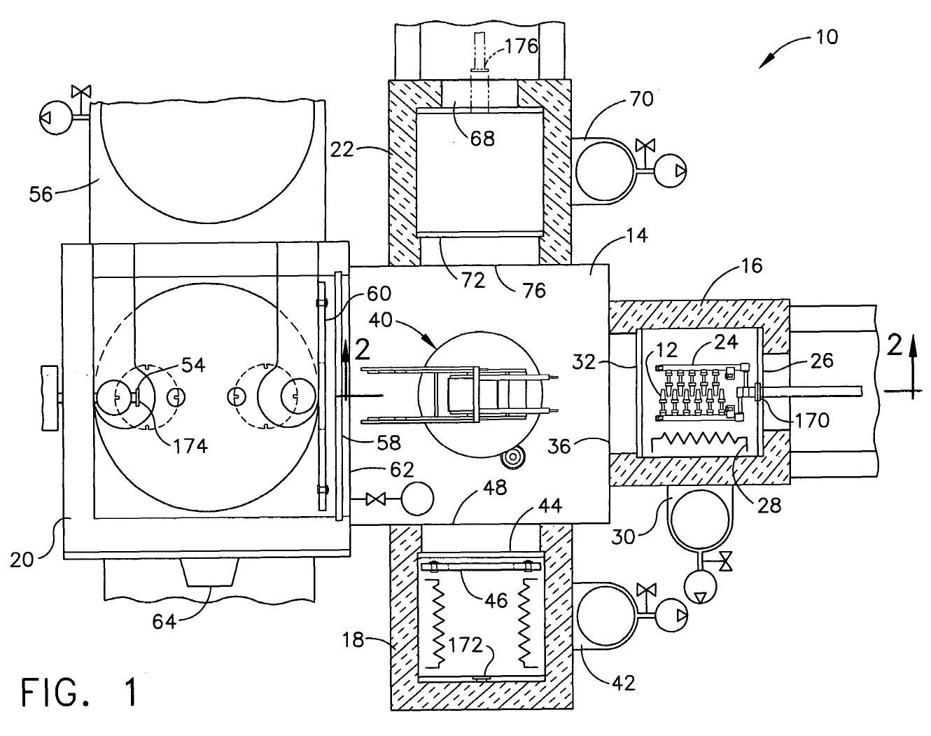

Referring now to the drawings in detail, wherein identical numerals indicate the same elements throughout the figures, FIG. 1 depicts a vacuum coating apparatus 10 which is utilized to apply a thermal barrier coating to workpieces 12 provided therein. More specifically, vacuum coating apparatus 10 preferably includes a substantially rectangular central chamber 14 (also known herein as an atrium) with a loading chamber 16, a heating chamber 18, a coating chamber 20, and an unloading chamber 22 positioned adjacent respective sides thereof.

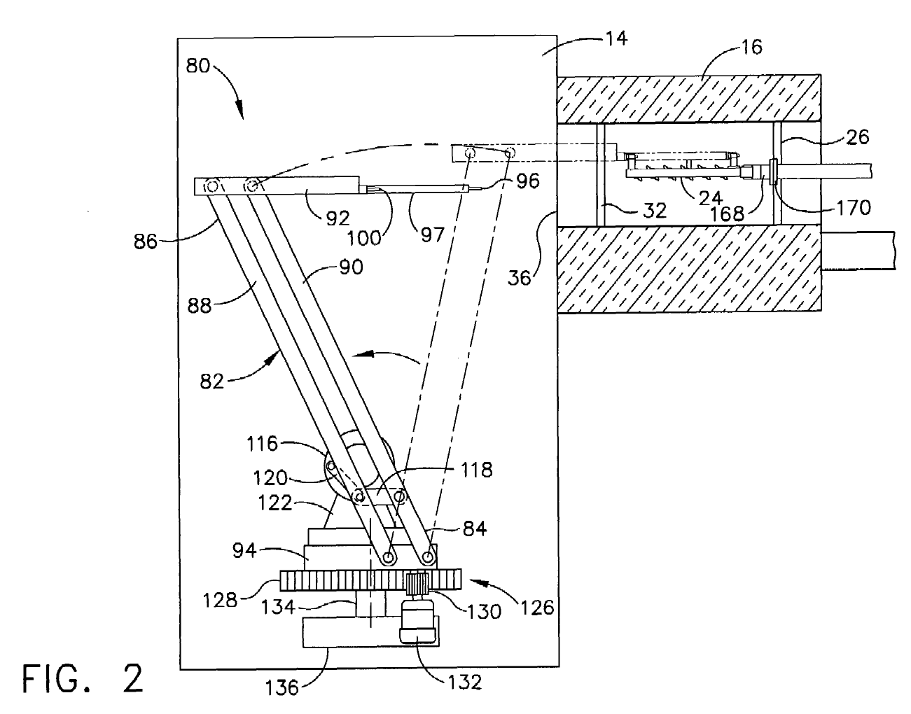

It will be appreciated from FIGS. 1 and 2 that a rake unit 24 having workpieces 12 loaded thereon is positioned in loading chamber 16 via a door or valve 26 located opposite central chamber 14. Loading chamber 16 may include pre-heating elements 28 (or infrared lamps) for outgassing rake unit 24 and workpieces 12. It will also be noted that a roughing pump 30 is preferably associated with loading chamber 16 in order to facilitate pumping therein after rake unit 24 has been loaded. A two way vacuum valve 32 is preferably provided adjacent a first side of central chamber 36 between loading chamber 16 and central chamber 14, where initially valve 32 is closed, loading chamber 16 is vented, and valve 26 associated with loading chamber 16 is opened so that rake unit 24 is brought into loading chamber 16. Afterward, valve 26 is closed and a desired vacuum condition in loading chamber 16 is initiated. When loading chamber 16 is sufficiently outgassed and heated, and an appropriate vacuum is attained, two way vacuum valve 32 is opened.

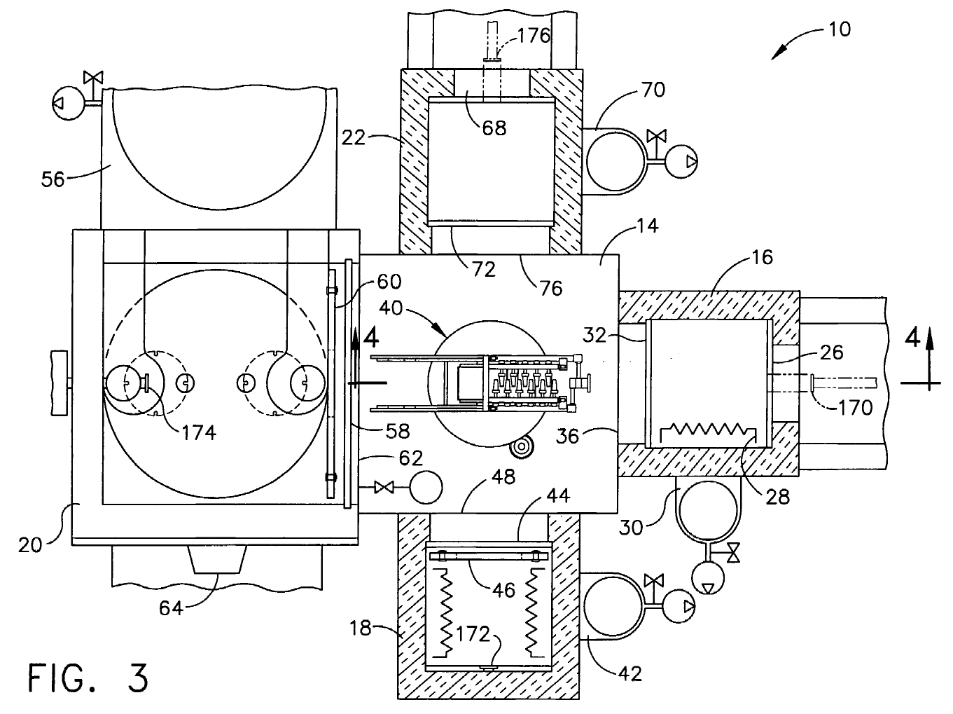

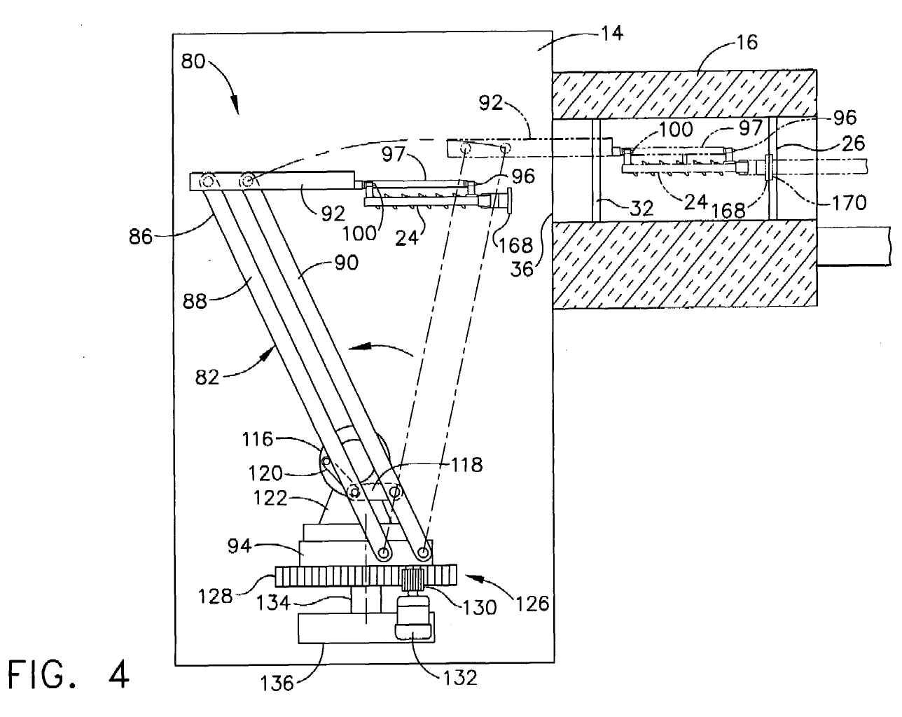

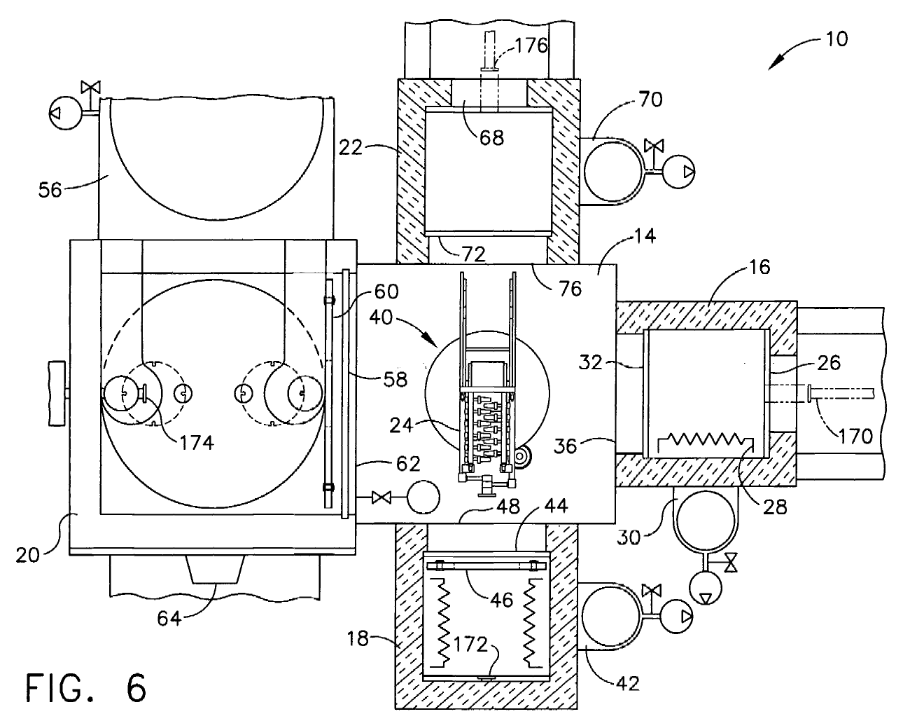

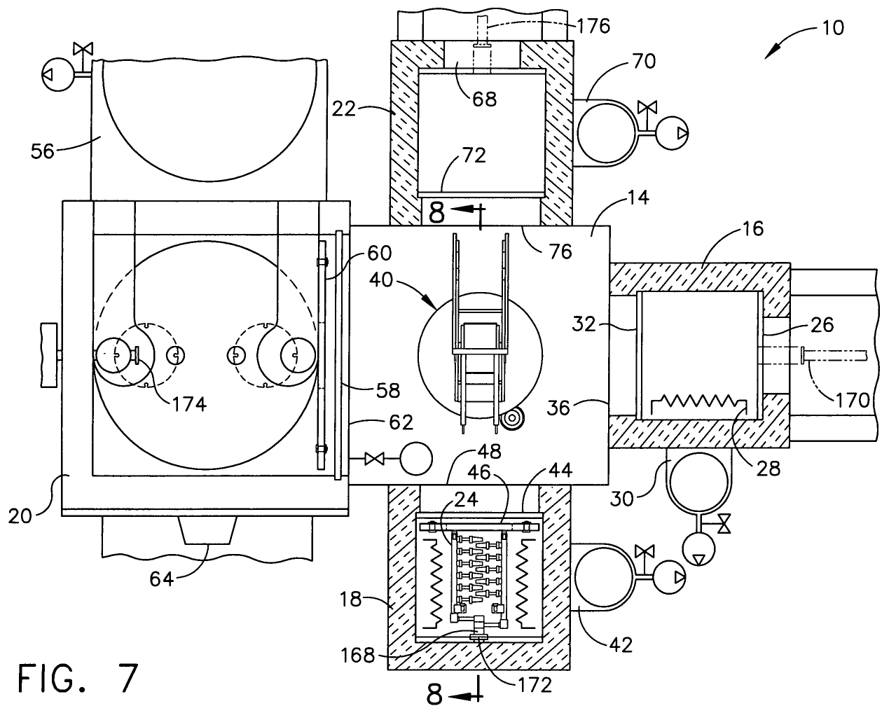

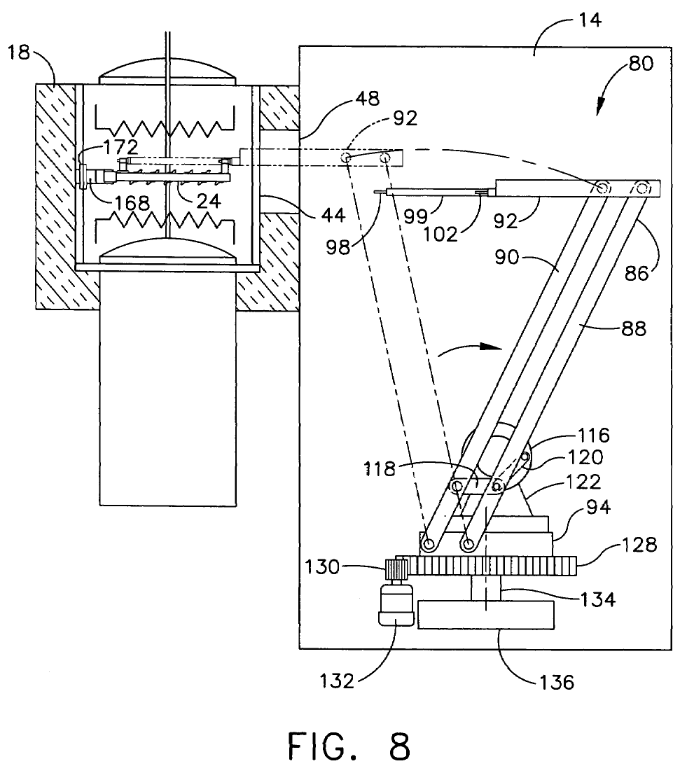

It will be appreciated that a mechanism identified generally by numeral 40 is utilized to transport rake unit 24 from loading chamber 16 into central chamber 14 (see FIGS. 3 and 4). In particular, it will be noted that transporting mechanism 40 first grabs rake unit 24 and pulls it into central chamber 14, where rake unit 24 is still oriented so as to still be in alignment with loading chamber 16. In order to transport rake unit 24 into heating chamber 18, transporting mechanism 40 rotates rake unit 24 approximately 90° in a clockwise direction so as to be in alignment with heating chamber 18 (see FIG. 6). Thereafter, transporting mechanism 40 pushes rake unit 24 into heating chamber 18 and releases it (see FIGS. 7 and 8). Rake unit 24 remains in heating chamber 18 for a predetermined time period or until workpieces 12 thereon reach a predetermined temperature.

As discussed previously with respect to loading chamber 16, it is preferred that heating chamber 18 include a separate vacuum pump 42 associated therewith to maintain the desired vacuum condition therein. A two way vacuum valve 44 is preferably positioned between central chamber 14 and heating chamber 18, whereby rake unit 24 may be maintained within a vacuum at all times within vacuum coating apparatus 10. It will be understood that valve 44 associated with a second side 48 of central chamber 14 remains closed until the desired vacuum condition and temperature are achieved within heating chamber 18. Thereafter, valve 44 is opened and rake unit 24 is transported into heating chamber 18. A heat shield 46 may optionally be provided between central chamber 14 and heating chamber 18 as well, where heat shield 46 is preferably located adjacent the heating chamber side of valve 44.

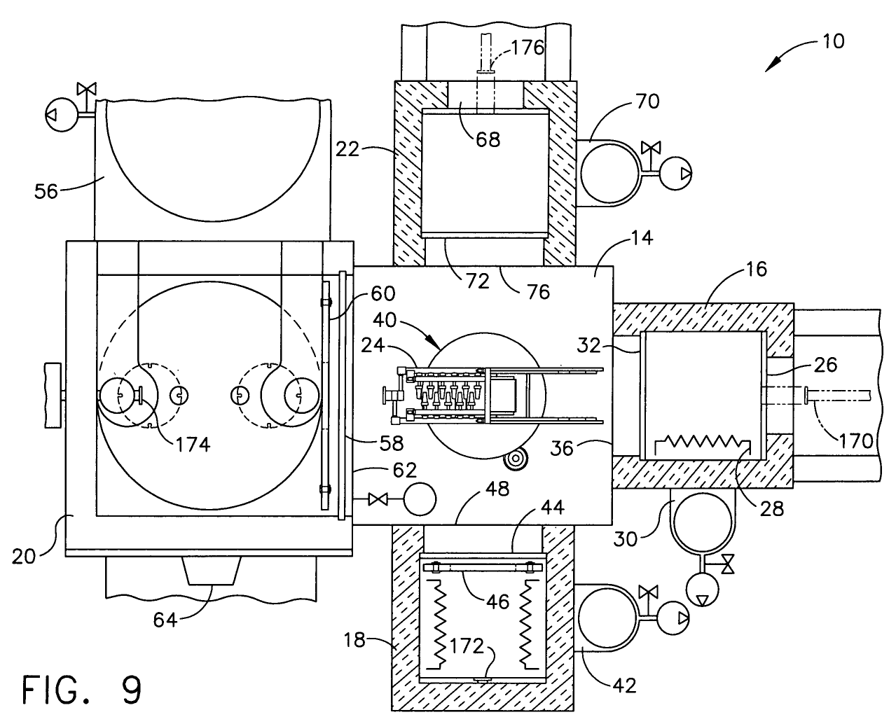

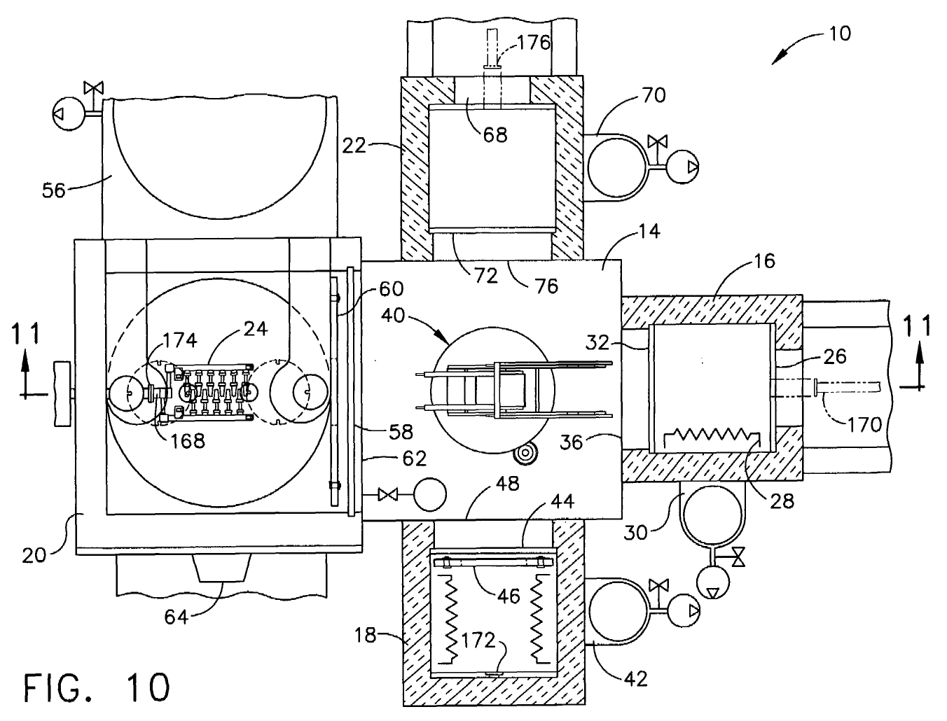

Once rake unit 24 has remained within heating chamber 18 for the predetermined time period and workpieces 12 have attained a desired temperature, transporting mechanism 40 is then utilized to remove rake unit 24 from heating chamber 18 and position it within coating chamber 20. This involves opening valve 44 and retracting heat shield 46, grabbing rake unit 24 and pulling it into central chamber 14, rotating rake unit 24 approximately 90° in a clockwise direction so as to be aligned with coating chamber 20, and then pushing rake unit 24 into coating chamber 20 (see FIGS. 9-11). It is preferred that rake unit 24 be docked on a specially configured receptacle 54 which enables workpieces 12 to be rotated, oscillated or otherwise moved during the coating process.

It is also preferred that coating chamber 20 include a separate vacuum pump 56 associated therewith to maintain the desired vacuum condition therein. A two way vacuum valve 58 is preferably positioned between central chamber 14 and coating chamber 20, whereby rake unit 24 may be maintained within a vacuum at all times within vacuum coating apparatus 10. It will be understood that a valve 58 associated with a third side 62 of central chamber 14 remains closed until the desired conditions are achieved within coating chamber 20. Thereafter, valve 58 is opened and rake unit 24 is transported into coating chamber 20. A heat shield 60 may also optionally be provided between central chamber 14 and coating chamber 20 as well. It will be appreciated that the present invention is not related to the specifics of coating chamber 20 and the process utilized therein to provide a thermal barrier coating to workpieces 12. Other than the fact that it is anticipated that coating chamber 20 may be useful for a variety of different workpieces, see U.S. Pat. Nos. 6,946,034 and 6,863,937 for detailed description of the coating process involved therein. A viewing port 64 is preferably provided for coating chamber 20 so that first rake unit 24 and workpieces 12 may be monitored during the coating process.

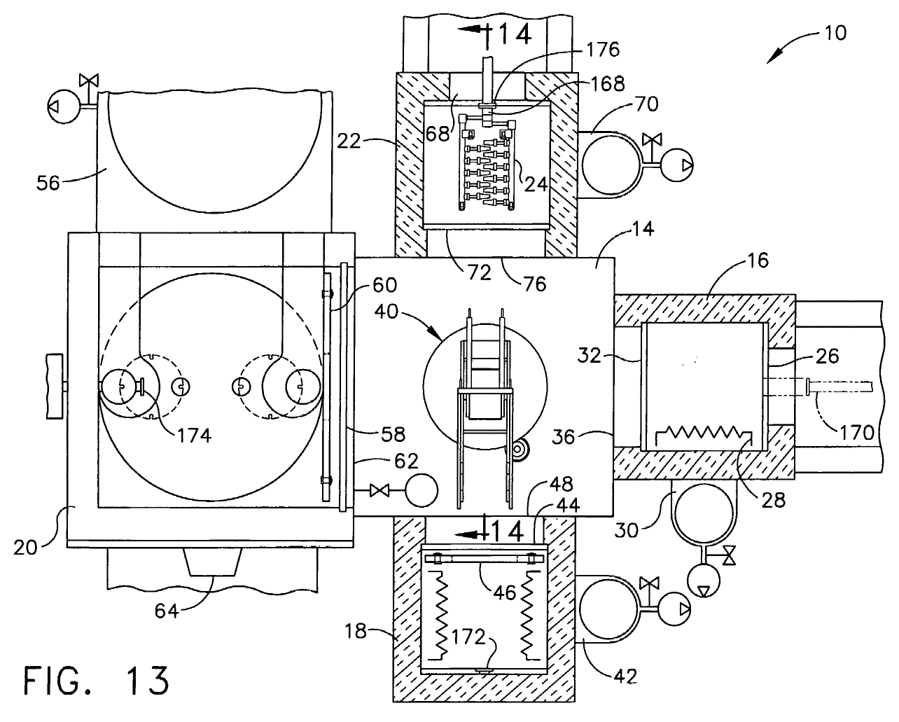

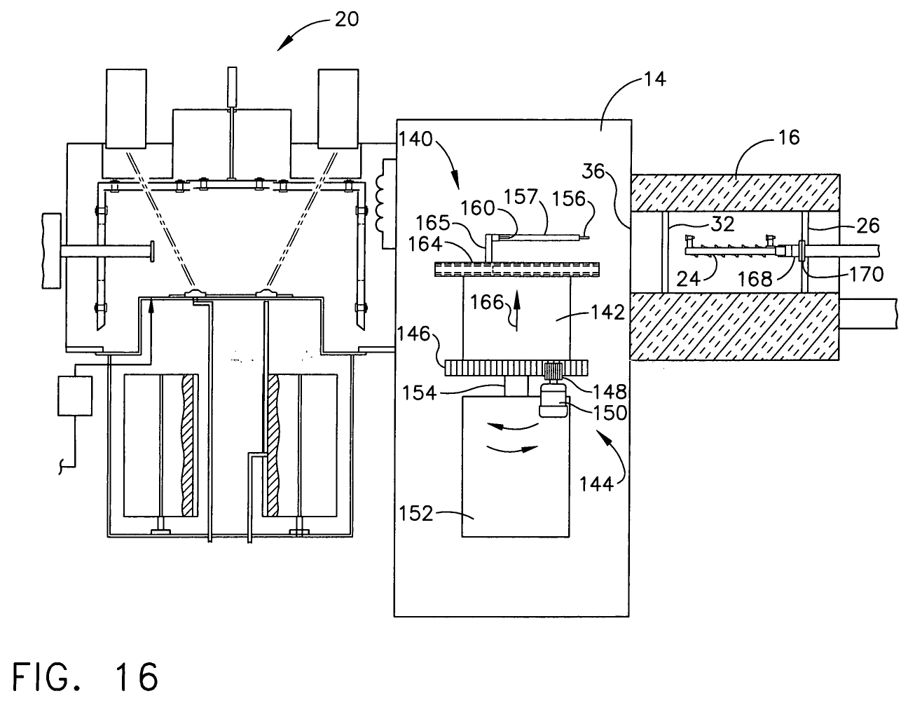

After the coating process for workpieces 12 has been completed, transporting mechanism 40 then removes rake unit 24 from coating chamber 20 and positions it within unloading chamber 22 (see FIGS. 12-14). This operation involves opening valve 58 and retracting heat shield 60, grabbing rake unit 24 and pulling it once again into central chamber 14, rotating rake unit 24 approximately 90° in a clockwise direction so as to be aligned with unloading chamber 22, and then pushing rake unit 24 into unloading chamber 22. Rake unit 24 and workpieces 12 may be permitted to cool for a predetermined time period, but typically are removed from unloading chamber 22 and vacuum coating apparatus 10 by means of a door (or valve) 68 located opposite of central chamber 14 (see FIG. 15) upon venting of unloading chamber 22.

As with the other chambers, it is preferred that unloading chamber 22 include a separate vacuum pump 70 associated therewith to maintain the desired vacuum condition therein. A two way vacuum valve 72 is preferably positioned between central chamber 14 and unloading chamber 22, whereby rake unit 24 may be maintained within a vacuum at all times within vacuum coating apparatus 10. It will be understood that valve 72 associated with a fourth side 76 of central chamber 14 remains closed until the desired vacuum conditions are achieved within unloading chamber 22. Thereafter, valve 72 is opened and rake unit 24 is transported into unloading chamber 22. Unloading chamber 22 is then vented so that valve 68 may be opened and rake unit 24 removed.

It will be appreciated from FIGS. 1, 3, 6-7, 9-10, 12-13 and 15 that loading chamber 16 and coating chamber 20 are located adjacent opposite sides 36 and 62 of central chamber. Likewise, heating chamber 18 and unloading chamber 22 are located adjacent opposite sides 48 and 76 of central chamber 14. This configuration minimizes the amount of rotation necessary to transport rake unit 24 between chambers for each successive step in the coating process or cycle. In the design depicted, the rotation occurs in a clockwise fashion, but the locations of heating chamber 18 and unloading chamber 22 may be switched and the rotation could take place in a counterclockwise manner. It will also be understood that depending upon the requirements or desires of a given situation, loading chamber 16 and unloading chamber 22 may be positioned on opposite sides of central chamber 14 (with heating chamber 18 and coating chamber 20 being positioned on opposite sides of central chamber 14) or loading chamber 16 and heating chamber 18 may be positioned on opposite sides of central chamber 14 (with coating chamber 20 and unloading chamber 22 being positioned on opposite sides of central chamber 14).

With respect to transporting mechanism 40, it will be seen from FIGS. 2, 4, 8, 11, and 14 that a manipulator arm 80 is included therewith to grab rake unit 24, where manipulator arm is movable in a manner so that rake unit 24 can be pulled into and pushed out of central chamber 14. Manipulator arm 80 preferably includes a main portion 82 which has a first end 84 and a second end 86. Although other configurations may be used, main portion 82 preferably includes a pair of substantially planar members 88 and 90 which are connected together in substantially parallel relation A support member 92 is connected to second ends 86 thereof.

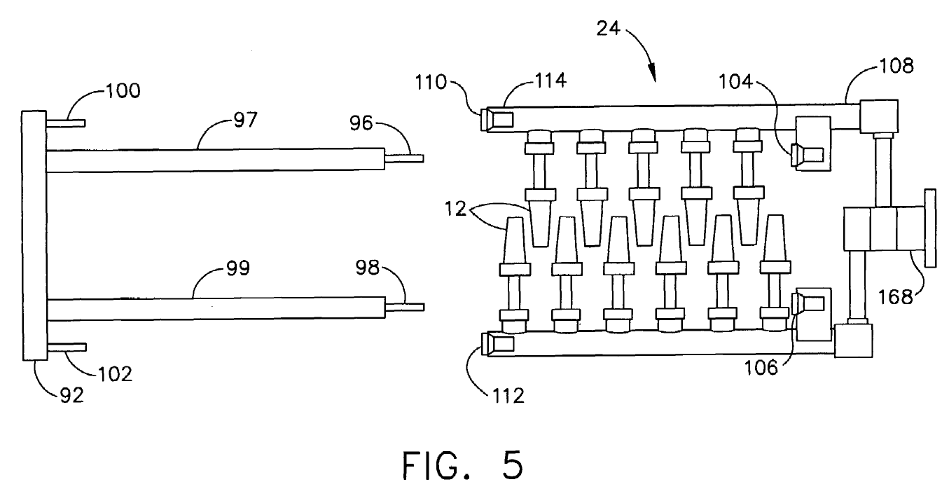

As best seen in FIG. 5, a first pair of lifting pins 96 and 98 and a second pair of lifting pins 100 and 102 are preferably connected to and extend from second end 86 of main portion 82 via support member 92. It will be appreciated that first lifting pins 96 and 98 include intermediate extension sections 97 and 99 so that first lifting pins 96 and 98 extend further than second lifting pins 100 and 102. As such, first lifting pins 96 and 98 are configured to engage a first pair of receptacles 104 and 106 located adjacent a first end 108 on rake unit 24 and second lifting pins 102 and 104 are configured to engage a second pair of receptacles 110 and 112 located adjacent a second end 114 on rake unit 24. In this way, the respective lifting pins are able to be connected to rake unit 24 so that rake unit 24 can be manipulated by manipulator arm 80.

A stepping motor 116 is preferably associated with main portion 82, wherein rotation of stepping motor 116 causes movement of main portion 82 and thereby enables first lifting pins 96 and 98 and second lifting pins 100 and 102 to extend into and out of central chamber 14. In particular, it will be seen that a first link member 118 is provided which connects planar members 88 and 90 and a second link member 120 is provided which connects stepping motor 116 to first link member 118. Stepping motor 116 is also connected to a base member 94 located below it via a motor mount 122. It will be appreciated that movement of stepping motor 116 causes main portion 82 to move in a slightly arcuate manner so that first lifting pins 96 and 98 and second lifting pins 100 and 102 move slightly higher or lower as they extend out of or into central chamber 14, respectively.

In order to rotate manipulator arm 80, and thereby align it (as well as rake unit 24 on some occasions) with the desired chamber as detailed herein, a turntable 126 is preferably associated with manipulator arm 80. More specifically, base member 94 is connected to a table gear 128, which is caused to rotate by a spur gear 130 powered by a motor 132. It will be seen that turntable 126 further includes a spindle 134 rotatably connecting table gear 128 to a base member 136. In order to make adjustments in the height of manipulator arm 80 with respect to the various chambers surrounding central chamber 14, it is preferred that some portion of manipulator arm 80 have the ability to telescope up and down. This may, for example, be accomplished via planar members 88 and 90 or by means of spindle 134.

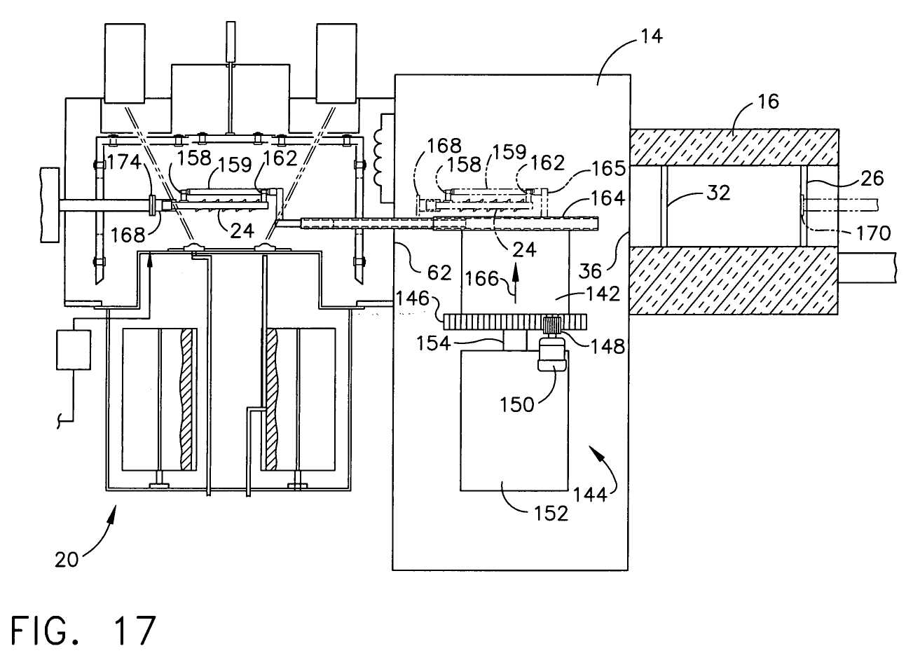

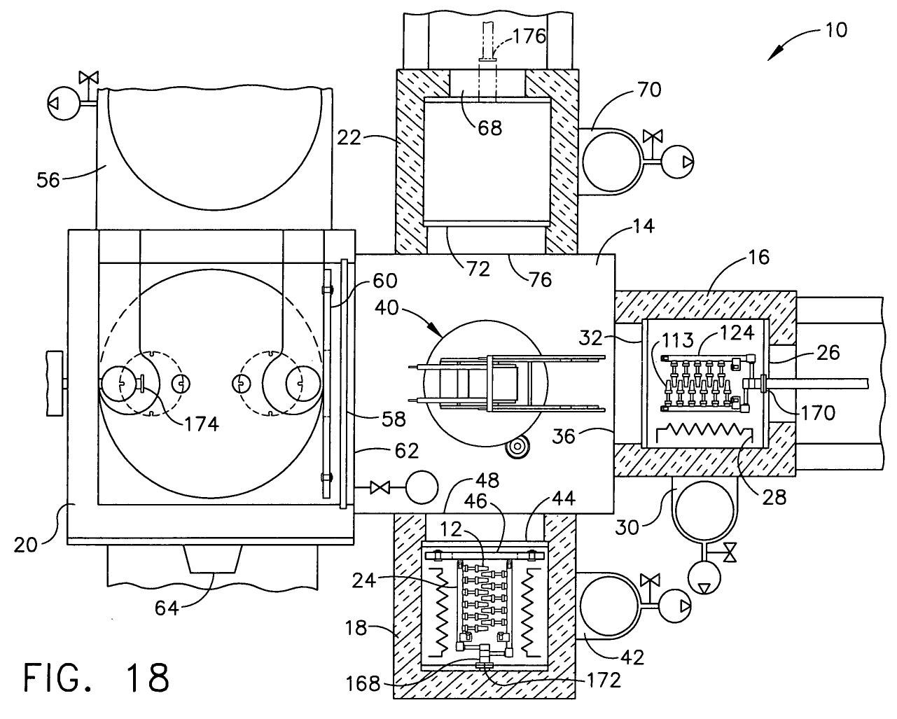

An alternative manipulator arm design is shown in FIGS. 16 and 17, where manipulator arm 140 includes a first base member 142 connected to a turntable 144. It will be appreciated that turntable 144 includes a table gear 146 and a spur gear 148 driven by a motor 150 which causes table gear 146 to rotate in either direction A second base member 152 is located beneath and preferably connected to table gear 146 by means of a spindle 154 so that table gear 146 (and first base member 142) is rotatable. A first pair of lifting pins 156 and 158 and a second pair of lifting pins 160 and 162 are preferably connected to an upper portion of first base member 142 via a support member 164 and an intermediate support member 165. First lifting pins 156 and 158 includes intermediate extension sections 157 and 159 so that first lifting pins 156 and 158 extend further from support member 164 than second lifting pins 160 and 162. It will be seen that first and second lifting pins 156, 158, 160 and 162 are preferably oriented substantially perpendicular to an axis 166 extending through spindle 154. In addition, support member 164 preferably has a telescoping feature as well so that first and second lifting pins 156, 158, 160 and 162, respectively, are able to extend out of and retract into central chamber 14. It will be appreciated that rake unit 24 must be positioned substantially within the same horizontal plane in order for manipulator arm 140, and particularly support member 164 and lifting pins 156, 158, 160 and 162, to be aligned therewith Alternatively, intermediate support member 165 could include a telescoping feature so as to adjust the height of manipulator arm 140 and bring lifting pins 156, 158, 160 and 162 into alignment with rake unit 24 as necessary for a particular adjacent chamber.

It will further be noted that rake unit 24 preferably includes a coupling mechanism 168 associated with first end 108 thereof (see FIG. 5). Coupling mechanism 168 functions to dock rake unit 24 with a respective mating coupler 170, 172, 174, and 176 in loading chamber 16, heating chamber 18, coating chamber 20 and unloading chamber 22. In this way, rake unit 24 is retained so that manipulator arm 80 is retracted into central chamber 14 while the desired operation takes place in such chamber.

It will be understood that transporting mechanism 40 is able to move a plurality of rake units 24 through the chambers of vacuum coating apparatus 10 during a single cycle. In this way, a plurality of rake units 24 simultaneously undergo a portion of a cycle therein. Further, a variety of different workpieces 12 are able to have coating operations performed thereon in an efficient manner since rake units 24 preferably are consistently configured so as to be transported with vacuum coating apparatus 10 and housed within the various chambers thereof. At the same time, it will be appreciated that the configuration of vacuum coating apparatus 10 enables rake units in loading chamber 16, heating chamber 18, and/or unloading chamber 22 to be removed therefrom and recovered with losing workpieces should a mishap occur within coating chamber 20.

In order to further appreciate the flexibility of vacuum coating apparatus 10 and the efficiency of transporting mechanism 40, the process for transporting rake unit 24 having a plurality of workpieces 12 thereon through vacuum coating apparatus 10 during a coating cycle is described by the following steps. As seen in FIGS. 1 and 2, a first rake unit 24 is initially provided to loading chamber 16. Once the appropriate conditions are satisfied within loading chamber 16, first rake unit 24 is engaged by first and second lifting pins 96, 98, 100 and 102, coupling mechanism 168 of rake unit 24 is decoupled from mating coupler 170, and rake unit 24 is pulled/carried from loading chamber into central chamber 14 by manipulator arm 80 (see FIGS. 3 and 4). First rake unit 24 is then rotated into alignment with heating chamber 18 by means of turntable 126 (see FIG. 6). Manipulator arm 80 extends away from central chamber 14 so that first and second lifting pins 96, 98, 100 and 102 push/carry first rake unit 24 into heating chamber 18 (see FIGS. 7 and 8). After coupling mechanism 168 of rake unit 24 engages with mating coupler 172, first and second lifting pins 96, 98, 100 and 102 disengage from first rake unit 24 and manipulator arm 80 positions them within central chamber 14. First rake unit 24 remains in heating chamber 18 for a predetermined time period so that workpieces 12 are heated to a predetermined temperature.

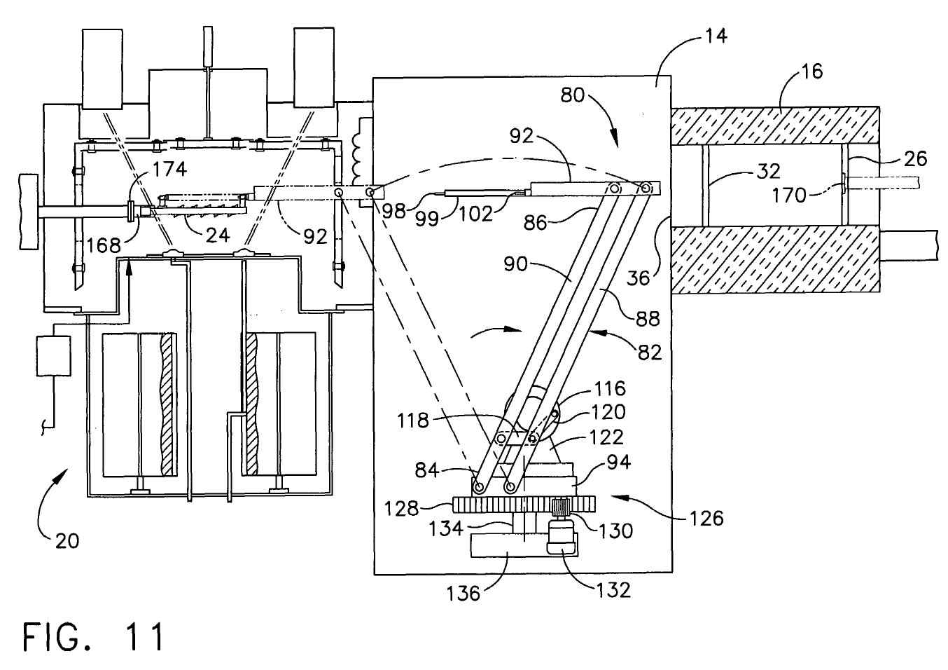

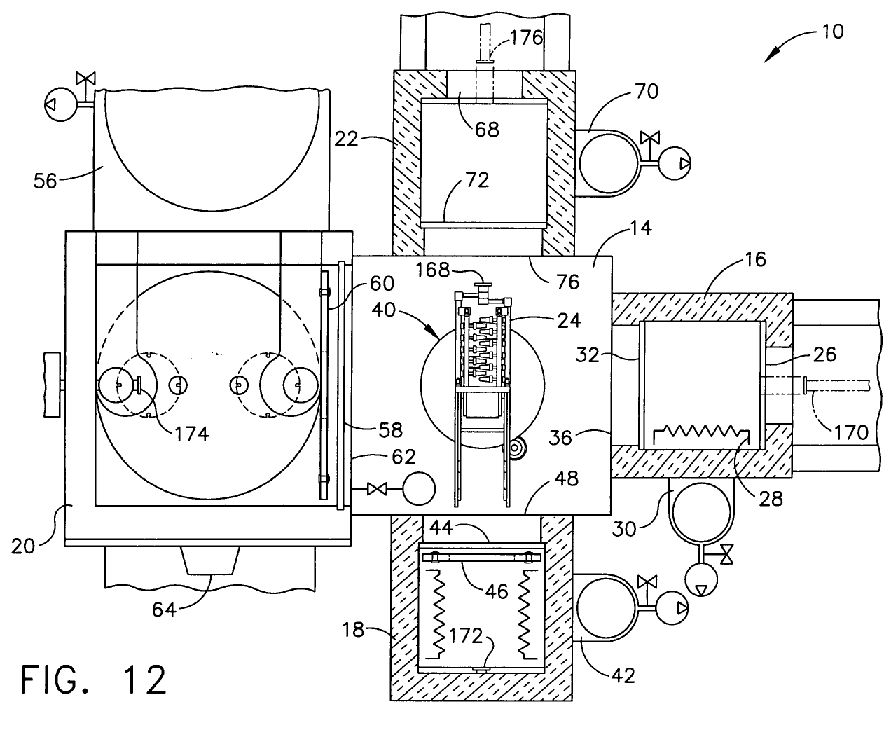

Once the predetermined temperature conditions are reached, manipulator arm 80 again causes first and second lifting pins 96, 98, 100 and 102 to engage first rake unit 24, coupling mechanism 168 is decoupled from mating coupler 172, and rake unit 24 is pulled/carried from heating chamber 18 into central chamber 14 by manipulator arm 80. First rake unit 24 is rotated into alignment with coating chamber 20 by means of turntable 126 (see FIG. 9). Manipulator arm 80 then extends away from central chamber 14 and first and second lifting pins 96, 98, 100 and 102 push/carry first rake unit 24 into coating chamber 20 until coupling mechanism 168 of first rake unit 24 engages coupling mechanism 174. First and second lifting pins 96, 98, 100 and 102 then disengage from first rake unit 24 and manipulator arm 80 pulls them into central chamber 14 so that workpieces 12 are coated with a thermal barrier coating in coating chamber 20 as desired (see FIGS. 10 and 11).

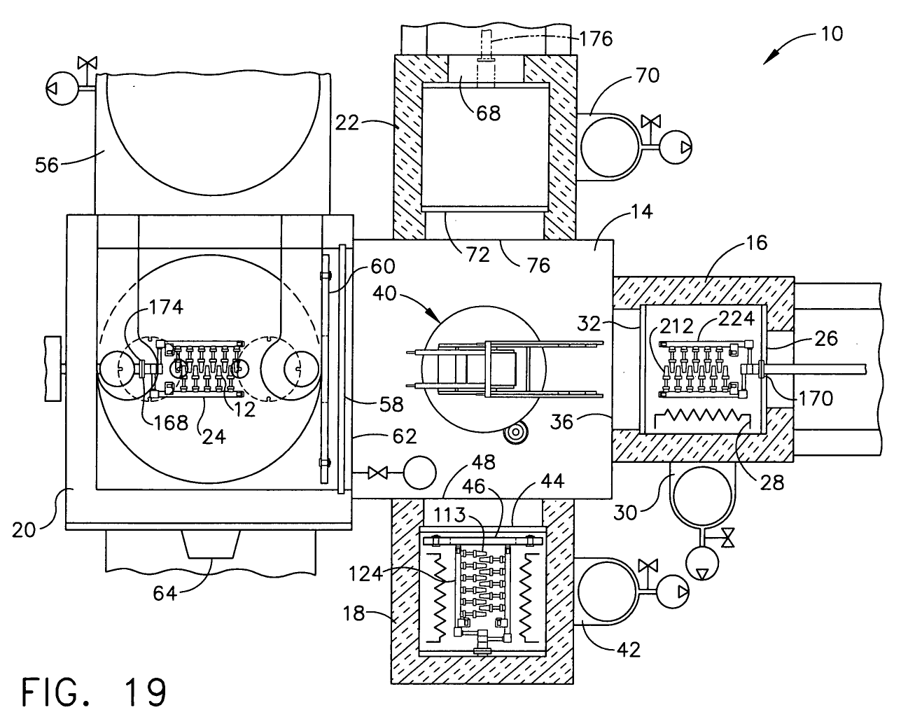

It will also be recognized that a second rake unit 124 is preferably provided to loading chamber 16 as first rake unit 24 is positioned within heating chamber 18 (see FIG. 18). After first rake unit 24 is positioned within coating chamber 20, second rake unit 124 is engaged by first and second lifting pins 96, 98, 100 and 102, coupling mechanism 168 is disengaged from mating coupler 170, and second rake unit 124 is pulled/carried from loading chamber 16 into central chamber 14 by manipulator arm 80. Second rake unit 124 is then rotated into alignment with heating chamber 18 by means of turntable 126. Manipulator arm 80 extends away from central chamber 14 and first and second lifting pins 96, 98, 100 and 102 push/carry second rake unit 124 into heating chamber 18 (see FIG. 19). After coupling mechanism 168 engages mating coupler 172, first and second lifting pins 96, 98, 100 and 102 disengage from second rake unit 124 and are positioned within central chamber 14 by manipulator arm 80. Second rake unit 124 remains in heating chamber 18 for a predetermined time period so that workpieces 113 are heated to a predetermined temperature. A third rake unit 224 is preferably provided to loading chamber 16 while first rake unit 24 is positioned within coating chamber 20 and second rake unit 124 is positioned within heating chamber 18.

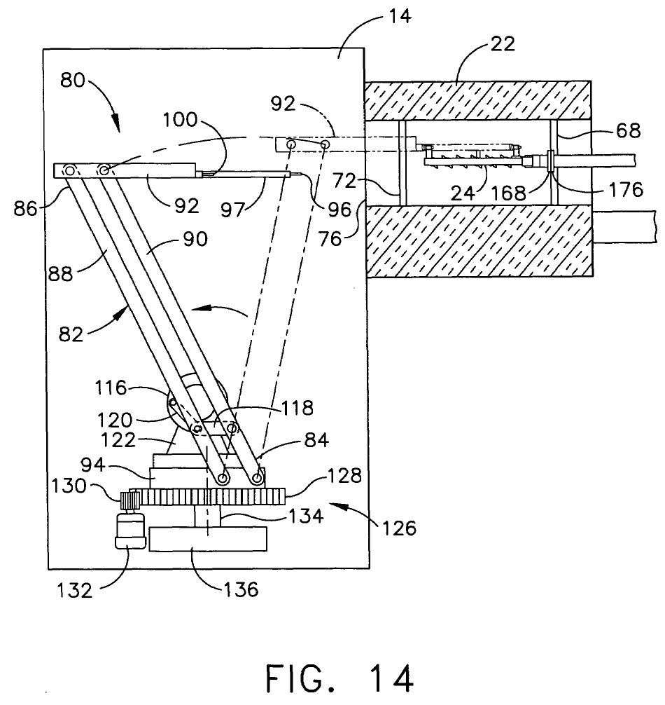

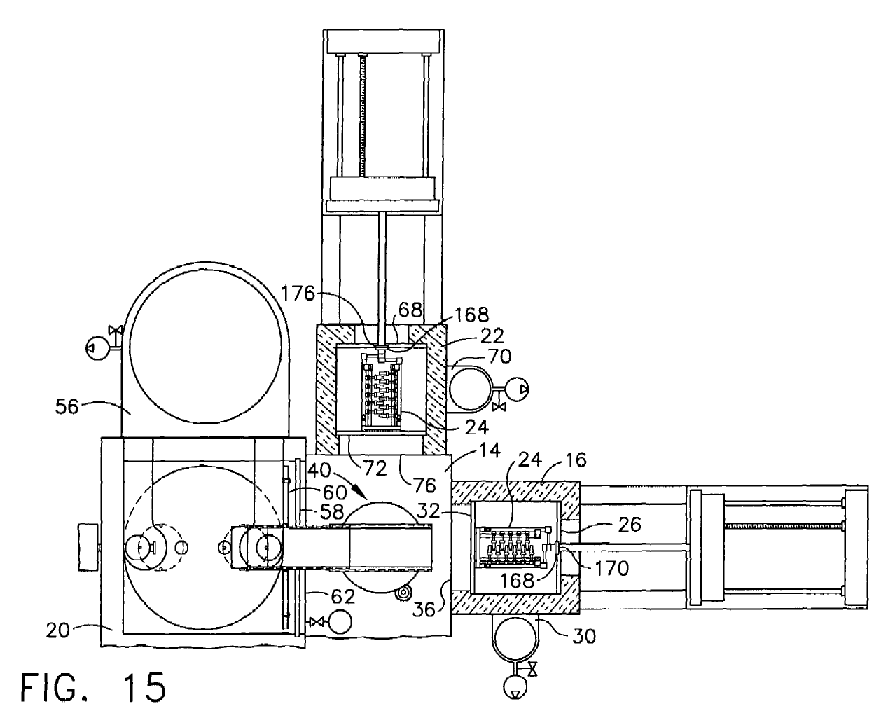

After the coating process for workpieces 12 of first rake unit 24 is completed, first and second lifting pins 96, 98, 100 and 102 of manipulator arm 80 engage first rake unit 24, coupling mechanism 168 is decoupled from mating coupler 174, and first rake unit 24 is pulled/carried into central chamber 14 by manipulator arm 80, whereupon first rake unit 24 is rotated into alignment with unloading chamber 22 by means of turntable 126 (see FIG. 12). First rake unit 24 is then pushed/carried from central chamber 14 into unloading chamber 22 by means of manipulator arm 80, coupling mechanism 168 engages mating coupler 176, and first and second lifting pins 96, 98, 100 and 102 are retracted into central chamber 14 (see FIGS. 13 and 14). It will be understood that first rake unit 24 remains in unloading chamber 22 until venting of such chamber has occurred. Thereafter, first rake unit 24 is removed from unloading chamber 22 via valve 68.

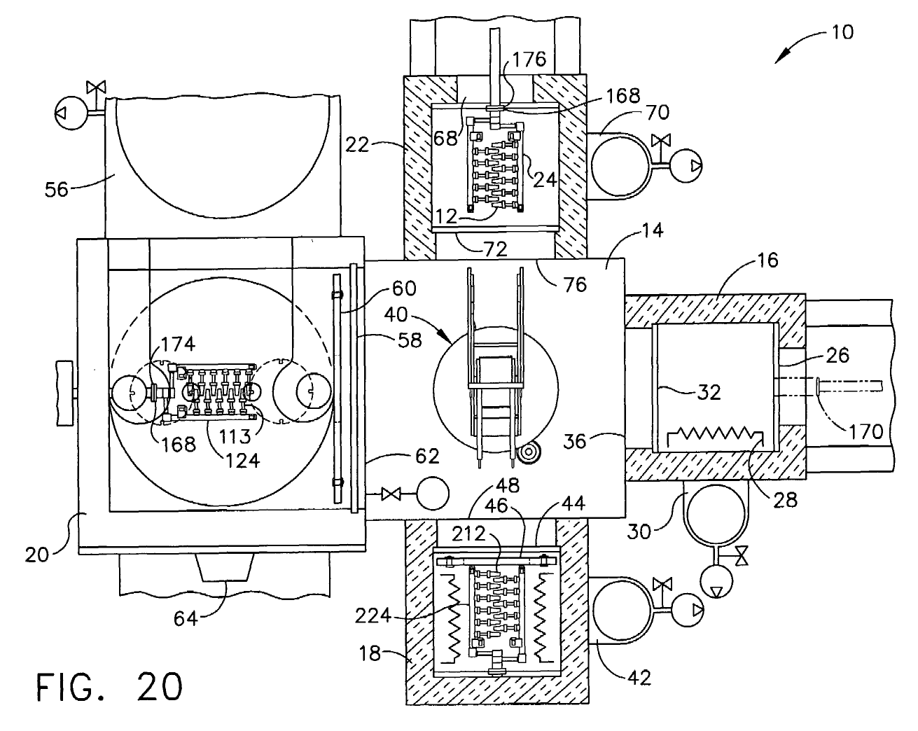

After first rake unit 24 is positioned within unloading chamber, manipulator arm 80 causes first and second lifting pins 96, 98, 100 and 102 to engage second rake unit 124, coupling mechanism 168 is disengaged from mating coupler 172, and second rake unit 124 is pulled/carried from heating chamber 18 into central chamber 14. Second rake unit 124 is rotated into alignment with coating chamber 20 by means of turntable 126. Manipulator arm 80 then extends away from central chamber 14 and first and second lifting pins 96, 98, 100 and 102 push/carry second rake unit 124 into coating chamber 20 until coupling mechanism 168 of second rake unit 124 engages mating coupler 174. First and second lifting pins 96, 98, 100 and 102 then disengage from second rake unit 124 and are retracted into central chamber 14 by manipulator arm 80. Workpieces 113 loaded on second rake unit 124 are then coated with a thermal barrier coating as desired (see FIG. 20).

While workpieces 12 of first rake unit are being unloaded and workpieces 113 of second rake unit 124 are undergoing the coating process, third rake unit 224 is engaged by first and second lifting pins 96, 98, 100 and 102, coupling mechanism 168 is detached from mating coupler 170, and third rake unit 224 is pulled/carried from loading chamber 16 into central chamber 14 by manipulator arm 80. Third rake unit 224 is then rotated into alignment with heating chamber 18 by means of turntable 126. Manipulator arm 80 extends away from central chamber 14 and first and second lifting pins 96, 98, 100 and 102 push/carry third rake unit 224 into heating chamber 18 (see FIG. 20). After coupling mechanism 168 engages mating coupler 172, first and second lifting pins 96, 98, 100 and 102 disengage from third rake unit 224 and are retracted into central chamber 14 by manipulator arm 80. Third rake unit 224 remains therein for a predetermined time period so that workpieces 212 loaded thereon are heated to a predetermined temperature. Accordingly, it will be appreciated that a plurality of rake units may be transported within vacuum coating apparatus 10 so that the workpieces of each may undergo a portion of the coating cycle therein simultaneously. Although not shown, a fourth rake unit may be provided within loading chamber 16.

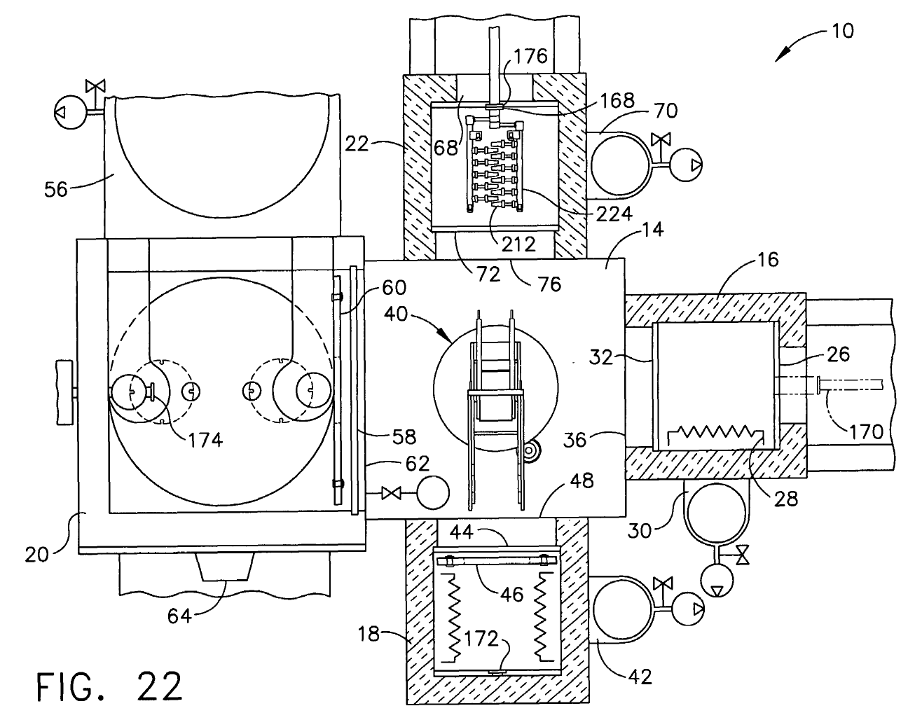

After the coating process for workpieces 113 of second rake unit 124 is completed, first and second lifting pins 96, 98, 100 and 102 engage second rake unit 124, coupling mechanism 168 is disengaged from mating coupler 174, and second rake unit 124 is pulled/carried into central chamber 14. Second rake unit 124 is then rotated into alignment with unloading chamber 22 and pushed/carried from central chamber 14 into unloading chamber 22 (see FIG. 22). Coupling mechanism 168 then attaches to mating coupler 176 and first and second lifting pins 96, 98, 100 and 102 are retracted into central chamber 14. It will be understood that second rake unit 124 then remains in unloading chamber 22 until chamber 22 is vented. Thereafter, second rake unit 124 is removed from unloading chamber 22 via valve 68.

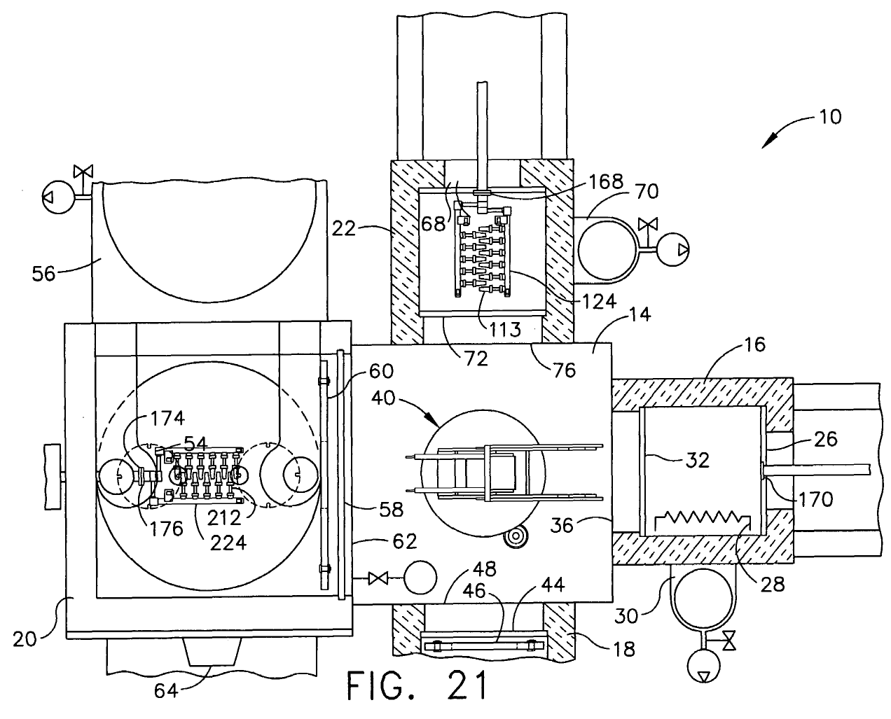

After second rake unit 124 is positioned within unloading chamber 22, manipulator arm 80 causes first and second lifting pins 96, 98, 100 and 102 to engage third rake unit 224, coupling mechanism 168 is disengaged from mating coupler 172, and third rake unit 224 is pulled/carried from heating chamber 18 into central chamber 14. Third rake unit 224 is rotated into alignment with coating chamber 20 by means of turntable 126. Manipulator arm 80 then extends away from central chamber 14 and first and second lifting pins 96, 98, 100 and 102 push/carry third rake unit 224 into coating chamber 20 until third rake unit 224 engages mating coupler 174. First and second lifting pins 96, 98, 100 and 102 then disengage from third rake unit 224 and workpieces 212 loaded thereon are coated with a thermal barrier coating as desired (see FIG. 21).

After the coating process for workpieces 212 of third rake unit 224 is completed, first and second lifting pins 96, 98, 100 and 102 of manipulator arm 80 engage third rake unit 224, coupling mechanism 168 is detached from mating coupler 174, and third rake unit 224 is pulled/carried into central chamber 14, whereupon third rake unit 224 is rotated into alignment with unloading chamber 22. Manipulator arm 80 then causes first and second lifting pins 96, 98, 100 and 102 to push/carry third rake unit 224 from central chamber 14 into unloading chamber 22 (see FIG. 22). It will be understood that third rake unit 224 then remains in unloading chamber 22 until such chamber 22 has vented. Thereafter, third rake unit 224 is removed from unloading chamber 22 via valve 68.

It will be appreciated that subsequent rake units may be loaded into vacuum coating apparatus 10 for coating operations in accordance with the sequence described herein. In this way, a constant, efficient flow of workpieces move throughout vacuum coating apparatus 10. Preferably, the coating process occurring within coating chamber 20, as well as the time required therefor, will dictate the movement of the other rake units within the other chambers of vacuum coating apparatus 10.

Having shown and described the preferred embodiment of the present invention, further adaptations of vacuum coating apparatus 10 and transporting mechanism 40, as well as the process for transporting workpieces therein, can be accomplished by appropriate modifications by one of ordinary skill in the art without departing from the scope of the invention Moreover, it will be understood that transporting mechanism 40 may be utilized with other types of vacuum coating apparatuses not depicted herein.

What is claimed is:

1. An apparatus for providing a vacuum coating to workpieces positioned on a rake unit, comprising:
(a) a substantially rectangular central chamber;
(b) a first chamber located adjacent said central chamber on a first side, wherein said rake unit is positioned in said first chamber after workpieces are loaded thereon;
(c) a second chamber located adjacent said central chamber on a second side, wherein workpieces on said rake unit are heated to a predetermined temperature;
(d) a third chamber located adjacent said central chamber on a third side, wherein workpieces on said rake unit are coated in a desired manner;
(e) a fourth chamber located adjacent said central chamber on a fourth side, wherein workpieces on said rake unit are unloaded; and, (f) a mechanism for transporting said rake unit from said first chamber to each of said second, third and fourth chambers in a desired sequence via said central chamber.

2. The apparatus of claim 1, said first chamber including a door positioned opposite said central chamber for loading said rake unit therein.

3. The apparatus of claim 1, said first chamber including pre-heating elements therein for outgassing said rake unit and said workpieces thereon.

4. The apparatus of claim 1, said first chamber including infrared lamps therein for outgassing said rake unit and said workpieces thereon.

5. The apparatus of claim 1, further comprising a roughing pump associated with said first chamber to facilitate pumping of said first chamber after said rake unit has been loaded therein.

6. The apparatus of claim 1, further comprising a two way vacuum valve positioned between said central chamber and said first chamber.

7. The apparatus of claim 1, further comprising a high vacuum pump associated with said central chamber for maintaining a vacuum condition therein.

8. The apparatus of claim 1, further comprising a heat shield positioned between said central chamber and said second chamber.

9. The apparatus of claim 1, further comprising a two way vacuum valve positioned between said central chamber and said second chamber.

10. The apparatus of claim 1, further comprising a vacuum pump associated with said second chamber for maintaining a vacuum condition therein.

11. The apparatus of claim 1, further comprising a vacuum pump associated with said third chamber for maintaining a vacuum condition therein.

12. The apparatus of claim 1, further comprising a vacuum pump associated with said fourth chamber.

13. The apparatus of claim 1, said third chamber including a receptacle therein for docking said rake unit so that rotation, oscillation or other movement is provided to said workpieces during coating.

14. The apparatus of claim 1, further comprising a heat shield positioned between said central chamber and said third chamber.

15. The apparatus of claim 1, further comprising a two way vacuum valve positioned between said central chamber and said third chamber.

16. The apparatus of claim 1, further comprising a two way vacuum valve positioned between said central chamber and said fourth chamber.

17. The apparatus of claim 1, said fourth chamber including a door positioned opposite said central chamber for unloading said rake unit therefrom.

18. The apparatus of claim 1, wherein said first and third chambers are located on opposite sides of said central chamber.

19. The apparatus of claim 1, wherein said first and fourth chambers are located on opposite sides of said central chamber.

20. The apparatus of claim 1, wherein said first and second chambers are located on opposite sides of said central chamber.

21. The apparatus of claim 1, said transporting mechanism further comprising:
(a) a manipulator arm configured to grab said rake unit, said manipulator arm being movable so that said rake unit is pulled into and pushed out of said central chamber; and,
(b) a turntable associated with said manipulator arm, wherein an orientation of said rake unit with respect to said central chamber is controlled by rotation thereof.

22. The apparatus of claim 21, said manipulator arm further comprising:
(a) a main portion having a first end and a second end;
(b) at least one pair of lifting pins connected to and extending from said second end of said main portion;
(c) a stepping motor connected to said first end of said main portion, wherein rotation of said stepping motor causes movement of said main portion which enables said lifting pins to extend into and out of said central chamber;
(d) a base member to which said stepping motor is connected, said base member being connected to said turntable so that said lifting pins rotate in accordance with said turntable.

23. The apparatus of claim 22, said main portion of said manipulator arm further comprising a pair of substantially planar members connected together in parallel.

24. The apparatus of claim 23, wherein said planar members telescope to raise and lower said lifting pins.

25. The apparatus of claim 21, said manipulator arm further comprising:
(a) a first base member connected to said turntable so as to rotate in accordance therewith;
(b) a second base member located beneath said first base member;
(c) a spindle connecting said first and second base members;
(d) a telescoping support member connected to said first base member, said support member being oriented substantially perpendicular to an axis through said spindle connecting said first and second base members; and,
(e) at least one pair of lifting pins associated with said support member, wherein said lifting pins are extendable out of and retractable into said central chamber.

26. The apparatus of claim 25, wherein said spindle telescopes to raise and lower said first base member.

27. The apparatus of claim 25, further comprising an intermediate support member connecting said telescoping support member and said lifting pins, said intermediate support member being oriented substantially perpendicular to said telescoping support member and said lifting pins.

28. The apparatus of claim 27, wherein said intermediate support member telescopes to raise and lower said lifting pins.

29. The apparatus of claim 1, wherein said transporting mechanism moves a plurality of rake units through said chambers of said vacuum coater during a single cycle.

30. The apparatus of claim 1, wherein a plurality of rake units simultaneously undergo a portion of a cycle in said vacuum coater.

31. The apparatus of claim 1, wherein a variety of different workpieces may be loaded on said rake unit.

32. A process for transporting a rake unit having a plurality of workpieces thereon through a vacuum coater during a coating cycle, comprising the following steps:
(a) providing a first rake unit to a loading chamber;
(b) pulling said first rake unit from said loading chamber into a central chamber;
(c) rotating said first rake unit into alignment with a heating chamber;
(d) pushing said first rake unit from said central chamber into said heating chamber for a predetermined time period;
(e) pulling said first rake unit from said heating chamber into said central chamber;
(f) rotating said first rake unit into alignment with a coating chamber;
(g) pushing said first rake unit from said central chamber into a coating chamber until docked therein;
(h) pulling said first rake unit from said coating chamber into said central chamber after a coating procedure has been applied to said workpieces;
(i) rotating said first rake unit into alignment with an unloading chamber;
(j) pushing said first rake unit from said central chamber into said unloading chamber; and,
(k) removing said first rake unit from said unloading chamber after a predetermined cooling period.

33. The process of claim 32, wherein rotation of said first rake unit from said loading chamber to said heating chamber, from said heating chamber to said coating chamber, and from said coating chamber to said unloading chamber is each approximately 90°.

34. The process of claim 32, further comprising the step of providing a second rake unit to said loading chamber as said first rake unit is positioned within said heating chamber.

35. The process of claim 34, further comprising the following steps after said first rake unit is positioned within said coating chamber:
(a) pulling said second rake unit from said loading chamber into said central chamber;
(b) rotating said second rake unit into alignment with said heating chamber; and,
(c) pushing said second rake unit from said central chamber into said heating chamber for a predetermined time period.

36. The process of claim 35, further comprising the step of providing a third rake unit to said loading chamber while said first rake unit is in said coating chamber and said second rake unit is in said heating chamber.

37. The process of claim 35, further comprising the following steps after said first rake unit is positioned within said unloading chamber:
(a) pulling said second rake unit from said heating chamber into said central chamber;
(b) rotating said second rake unit into alignment with said coating chamber; and,
(c) pushing said second rake unit from said central chamber into said coating chamber until docked therein.

38. The process of claim 37, further comprising the following steps after said second rake unit is positioned within said coating chamber:
(a) pulling said third rake unit from said loading chamber into said central chamber;
(b) rotating said third rake unit into alignment with said heating chamber; and,
(c) pushing said third rake unit from said central chamber into said heating chamber for a predetermined time period.

39. The process of claim 38, further comprising the step of removing said first rake unit from said unloading chamber while said second rake unit undergoes a coating procedure.

40. The process of claim 39, further comprising the following steps after said second rake unit has undergone said coating procedure:
(a) pulling said second rake unit from said coating chamber into said central chamber;
(b) rotating said second rake unit into alignment with said unloading chamber; and,
(c) pushing said second rake unit from said central chamber into said unloading chamber.

41. The process of claim 40, further comprising the following steps after said second rake unit is positioned within said unloading chamber:
(a) pulling said third rake unit from said heating chamber into said central chamber;
(b) rotating said third rake unit into alignment with said coating chamber; and,
(c) pushing said third rake unit from said central chamber into said coating chamber until docked therein.

42. The process of claim 41, further comprising the step of removing said second rake unit from said unloading chamber while said third rake unit undergoes a coating procedure.

43. The process of claim 42, further comprising the following steps after said third rake unit has undergone said coating procedure:
(a) pulling said third rake unit from said coating chamber into said central chamber;
(b) rotating said third rake unit into alignment with said unloading chamber; and,
(c) pushing said third rake unit from said central chamber into said unloading chamber.

44. The process of claim 43, further comprising the step of removing said third rake unit from said unloading chamber.
